(19) United States
(12) Patent Application Publication
(10) Pub. No.: US 2025/0275424 A1
(43) Pub. Date: Aug. 28, 2025

(54) Display Device

(71) Applicant: LG Display Co., Ltd., Seoul (KR)

(72) Inventors: OhNam Kwon, Paju-si (KR); HunHoe Heo, Paju-si (KR)

(21) Appl. No.: 18/914,555

(22) Filed: Oct. 14, 2024

(30) Foreign Application Priority Data
Feb. 27, 2024 (KR) 10-2024-0028075

(51) Int. Cl. H10K 59/80; H10K 59/122

(52) U.S. Cl. CPC H10K 59/873; H10K 59/122

(57) ABSTRACT

Embodiments of the disclosure relate to a display device and may provide a display device capable of delaying the time when moisture and oxygen penetrate into the display area by including a metal layer disposed at a boundary between the display area and the non-display area, a protective layer positioned on the metal layer and including a first portion overlapping the metal layer and a second portion positioned on the substrate and not overlapping the metal layer, and a photosensitive resin layer positioned between the substrate and the second portion.

### CROSS-REFERENCE TO RELATED APPLICATION

This application claims priority from Republic of Korea Patent Application No. 10-2024-0028075, filed on Feb. 27, 2024, which is hereby incorporated by reference in its entirety.

### FIELD

Embodiments of the disclosure relate to a display device.

### BACKGROUND

The growth of the intelligent society leads to increased demand for various types of display devices.

In display industry, flat panel display devices (FPDs) that may be made slim and lightweight and in large-area screen, have been quickly replacing bulky cathode ray tubes (CRTs).

Flat panel display devices include liquid crystal displays (LCDs), plasma display panels (PDP), organic light emitting displays (OLED), and electrophoretic displays (ED).

Among them, the organic light emitting display device is a self-luminous device that emits light by itself, and has advantages such as fast response, high luminous efficiency and luminance, and a large viewing angle.

In particular, the organic light emitting display device may be formed on a flexible substrate, and may be driven at a lower voltage, consume less power, and exhibit a brisker color than the plasma display panel or the inorganic electroluminescent (EL) display.

### SUMMARY

Since the penetration of moisture and oxygen occurs very strongly in the organic film, an under-cut structure is applied to prevent or at least reduce the penetration of moisture and oxygen in the bezel portion, but there is a problem that the cathode electrode and the inorganic film adversely affect the formation of seamless step coverage due to the step of the undercut structure. Accordingly, the inventors of the disclosure have invented a display device in which a cathode electrode and an inorganic film may form seamless step coverage.

Embodiments of the disclosure may provide a display device capable of delaying the time when moisture and oxygen penetrate into the display area.

Embodiments of the disclosure may provide a display device capable of process optimization.

Embodiments of the disclosure may provide a display device comprising a substrate including a display area and a non-display area surrounding the display area, a metal layer disposed on the substrate and disposed at a boundary between the display area and the non-display area, a protective layer positioned on the metal layer and including a first portion overlapping the metal layer and a second portion positioned on the substrate and not overlapping the metal layer, and a photosensitive resin layer positioned between the substrate and the second portion.

Embodiments of the disclosure may provide a display device comprising a substrate including a display area and a non-display area surrounding the display area, a filler layer disposed on the substrate, disposed at a boundary between the display area and the non-display area, and including a first portion including a metal or an alloy thereof and a second portion including a photosensitive resin, and a protective layer positioned on the filler layer.

According to embodiments of the disclosure, there may be provided a display device capable of delaying the time when moisture and oxygen penetrate into the display area.

According to embodiments of the disclosure, there may be provided a display device capable of process optimization.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure.

FIGS. 2A and 2B are plan views illustrating an example of a position where an undercut area is provided in a display panel applied to a display device according to embodiments of the disclosure.

FIGS. 3A and 3B are enlarged plan views illustrating area X of FIGS. 2A and 2B according to embodiments of the disclosure.

FIGS. 4A and 4B are cross-sectional views taken along line I-I′ of FIG. 3A and line II-II′ of FIG. 3B according to embodiments of the disclosure.

FIG. 5 is a cross-sectional view illustrating an example of an undercut area provided in area X of FIGS. 2A and 2B according to embodiments of the disclosure.

FIG. 6 is an enlarged cross-sectional view illustrating area Y of FIG. 4A according to an embodiment of the disclosure.

FIG. 7 is an enlarged cross-sectional view illustrating area Y of FIG. 4A according to another embodiment of the disclosure.

FIGS. 8A, 8B, and 8C are views briefly illustrating a process of forming a partial area of a display panel according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In describing embodiments of the disclosure, the term “group” means the group of the periodic table of elements.

Further, in describing embodiments of the disclosure, “period” refers to the period of the periodic table of elements.

“Group II” may include group IIA (or 2A) and group IIB (or 2B), and group II elements may include, but are not limited to, Be, Mg, Ca, Sr, Zn, Cd, and Hg.

“Group III” may include group IIIA (or 3A) and group IIIB (or 3B), and group III elements may include, but are not limited to, In, Ga, Al, and Tl.

Hereinafter, various embodiments of the disclosure are described in detail with reference to the accompanying drawings.

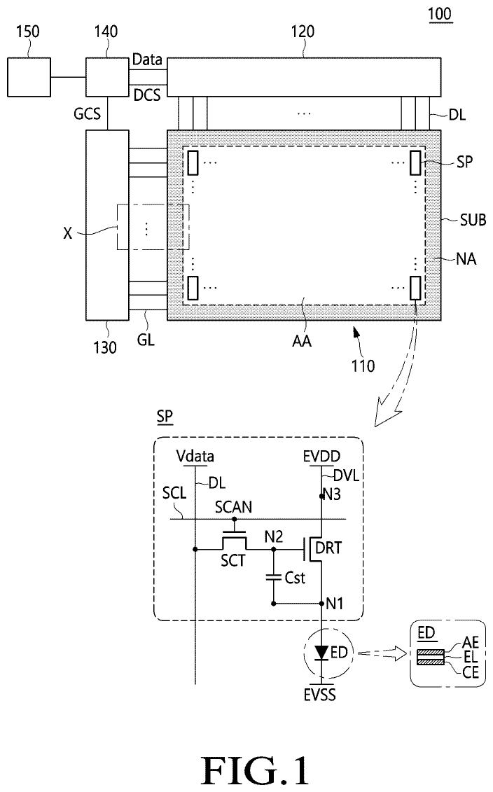

FIG. 1 is a view illustrating a system configuration of a display device according to embodiments of the disclosure.

Referring to FIG. 1, a display driving system of a display device 100 according to embodiments of the disclosure may include a display panel 110 and display driving circuits for driving the display panel 110.

The display panel 110 may include a display area AA in which images are displayed and a non-display area NA in which no image is displayed.

The display panel 110 may include a plurality of subpixels SP disposed on a substrate SUB for image display.

The display panel 110 may include a plurality of signal lines disposed on the substrate SUB.

For example, the plurality of signal lines may include data lines DL, gate lines GL, driving voltage lines, and the like.

Each of the plurality of data lines DL is disposed while extending in a first direction (e.g., a column direction or a row direction), and each of the plurality of gate lines GL is disposed while extending in a direction crossing the first direction.

The display driving circuits may include a data driving circuit 120 and a gate driving circuit 130 and may further include a controller 140 for controlling the data driving circuit 120 and the gate driving circuit 130.

The data driving circuit 120 may output data signals (also referred to as data voltages) corresponding to an image signal to the plurality of data lines DL.

The gate driving circuit 130 may generate gate signals and output the gate signals to the plurality of gate lines GL.

The controller 140 may convert the input image data input from an external host 150 to meet the data signal format used in the data driving circuit 120 and supply the converted image data to the data driving circuit 120.

The data driving circuit 120 may include one or more source driver integrated circuits.

For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NA of the display panel 110 by a gate in panel (GIP) method.

Referring to FIG. 1, in the display device 100 according to embodiments of the disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED.

The scan transistor SCT may transfer the data voltage Vdata to the second node N2 which is the gate node of the driving transistor DRT.

The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE.

The anode electrode AE may be a pixel electrode involved in forming the light emitting element ED of each subpixel SP and may be electrically connected to the first node N1 of the driving transistor DRT.

The cathode electrode CE may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

The driving transistor DRT is a transistor for driving the light emitting element ED, and may include a first node N1, a second node N2, and a third node N3.

The first node N1 may be a source node or a drain node, and may be electrically connected to the anode electrode AE of the light emitting element ED.

The second node N2 is a gate node and may be electrically connected to the source node or drain node of the scan transistor SCT.

The third node N3 may be a drain node or a source node, and may be electrically connected to a driving voltage line DVL that supplies the driving voltage EVDD.

For convenience of description, in the example described below, the first node N1 is a source node and the third node N3 may be a drain node.

The scan transistor SCT may switch the connection between the data line DL and the second node N2 of the driving transistor DRT.

In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors.

The plurality of subpixels SP may have the same structure, or some of the plurality of subpixels SP may have a different structure.

Each of the driving transistor DRT and the scan transistor SCT may be an n-type transistor or a p-type transistor.

The display device 100 according to embodiments of the disclosure may have a top emission structure or a bottom emission structure.

The top emission structure is described below as an example.

For example, in the top emission structure, the anode electrode AE may be a reflective metal, and the cathode electrode CE may be a transparent conductive film.

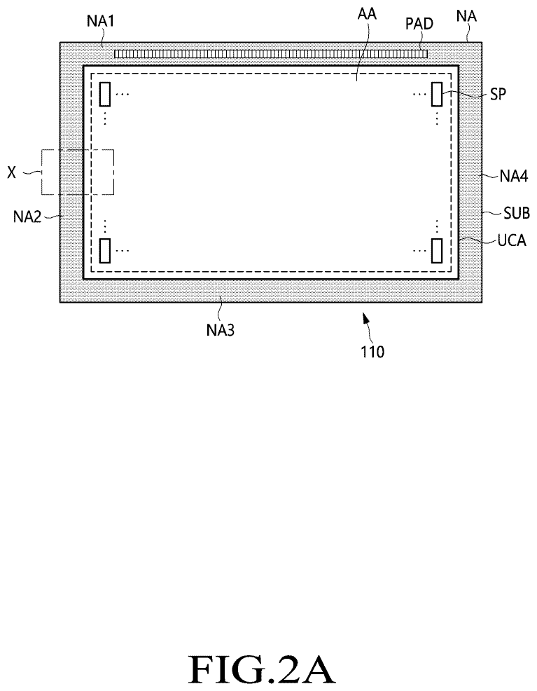

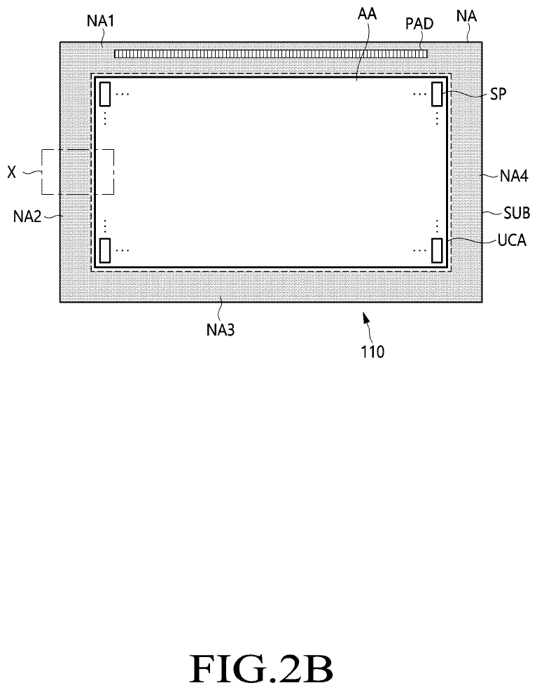

FIGS. 2A and 2B are plan views illustrating an example of a position where an undercut area is provided in a display panel applied to a display device according to embodiments of the disclosure.

Referring to FIGS. 2A and 2B, in the display panel 110 applied to the display device according to embodiments of the disclosure, the non-display area NA surrounds the display area AA.

The non-display area NA includes a first non-display area NA1 including a data driving circuit 120, a second non-display area NA2 including a gate driving circuit 130, a third non-display area NA3 facing the first non-display area NA1, and a fourth non-display area NA4 facing the second non-display area NA2.

Referring to FIGS. 2A and 2B, an undercut area UCA may be disposed along a boundary between the display area AA and the non-display area NA of the display panel 110.

The undercut area UCA may be disposed in any one of the display area AA or the non-display area NA, and may be disposed in both the areas.

For example, referring to FIG. 2A, the undercut area UCA may be disposed in the display area AA along a boundary between the display area AA and the non-display area NA.

Further, referring to FIG. 2B, the undercut area UCA may be disposed in the non-display area NA along a boundary between the display area AA and the non-display area NA.

The undercut area UCA may be disposed along a boundary line between the display area AA and at least one of the first to fourth non-display areas.

For example, the undercut area UCA may be disposed along a boundary line between the display area AA and the second non-display area NA2, and the undercut area UCA may be disposed along a boundary line between the display area AA and the first non-display area NA1 and the second non-display area NA2.

The undercut area UCA may be disposed along a boundary line between the display area AA and the first non-display area NA1 and the third non-display area NA3, and the undercut area UCA may be disposed along a boundary line between the display area AA and the second non-display area NA2 and the fourth non-display area NA4.

The undercut area UCA may be continuously disposed along the boundary line of the first non-display area NA1, or may be partially disposed.

The undercut area UCA may be continuously disposed along a boundary line of an adjacent non-display area.

For example, when the undercut area UCA is disposed on the boundary line between the display area AA and the first non-display area NA1 and the second non-display area NA2, the undercut area UCA may be continuously disposed along the boundary line between the first non-display area NA1 and the second non-display area NA2.

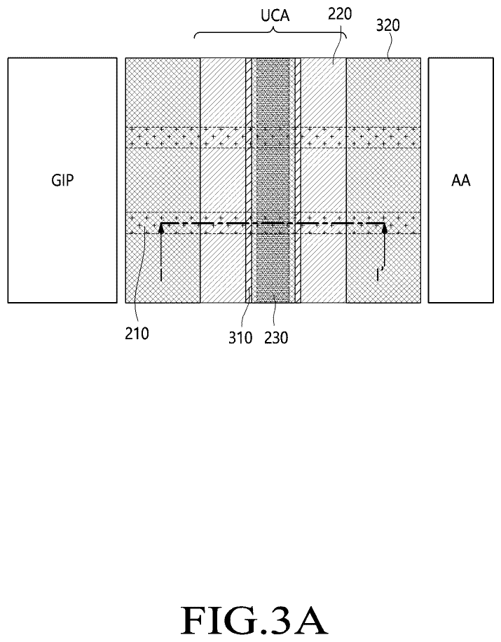

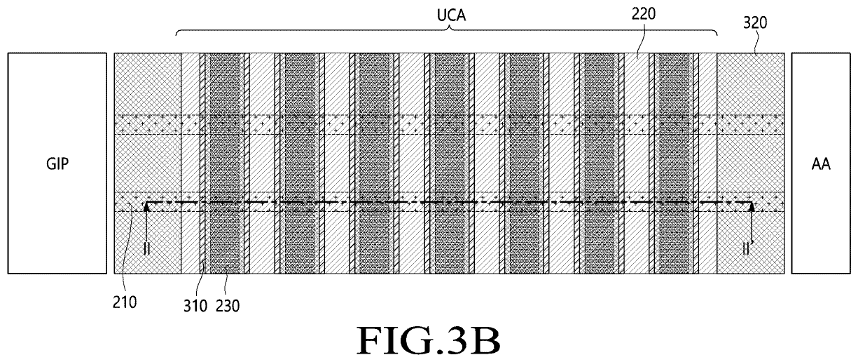

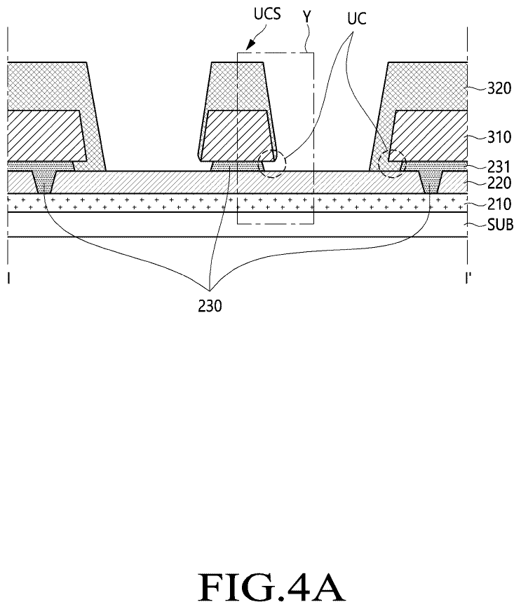

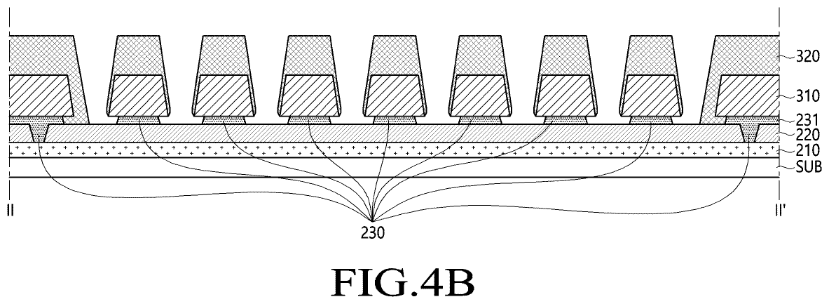

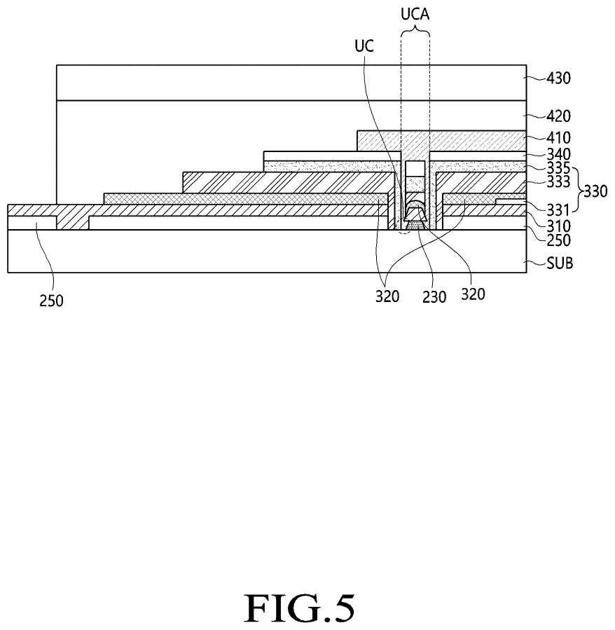

FIGS. 3A and 3B are enlarged plan views illustrating area X of FIGS. 2A and 2B according to embodiments of the disclosure, FIG. 4A is a cross-sectional view taken along line I-I′ of FIG. 3A according to embodiments of the disclosure, FIG. 4B is a cross-sectional view taken along line II-II′ of FIG. 3B according to embodiments of the disclosure, and FIG. 5 is a cross-sectional view illustrating an example of an undercut area provided in the X area of FIGS. 2A and 2B according to embodiments of the disclosure.

Hereinafter, embodiments of the disclosure are described using, in particular, the second non-display area NA2 in which the gate driving circuit 130 is provided in a GIP type among the non-display areas NA.

When the gate driving circuit 130 is provided in the GIP type in the fourth non-display area NA4 facing the second non-display area NA2, the structure of the fourth non-display area NA4 may be substantially the same as the structure of the second non-display area NA2.

In the disclosure, when A is substantially the same as B, it may mean that A and B are regarded as the same considering a tiny difference due to a processing error.

The first non-display area NA1 and the third non-display area NA3 may have substantially the same structure as the undercut area of the second non-display area NA2, except that the gate driving circuit 130 is not provided.

Referring to FIGS. 3A to 5, a display device 100 according to embodiments of the disclosure may include a substrate SUB including a display area AA for displaying an image by a plurality of subpixels and a non-display area NA surrounding the display area AA, metal layers 230 and 231 disposed on the substrate SUB and disposed at a boundary between the display area AA and the non-display area NA, a protective layer 310 disposed on the metal layers 230 and 231, and an undercut structure UC disposed along a boundary between the display area AA and the non-display area NA, and the undercut area UCA may include a protective layer disposed on the substrate SUB and disposed at a boundary between the display area AA and the non-display area NA. An undercut structure UC in which an edge of the layer 310 protrudes may be included.

The display device 100 according to embodiments of the disclosure may include an anode electrode 331 disposed on a protective layer 310, a bank layer 320 disposed on the anode electrode 331, a light emitting layer 333 disposed on the anode electrode 331 and the bank layer 320, a cathode electrode 335 disposed on the light emitting layer 333, a capping layer 340 disposed on the cathode electrode 335, a passivation layer 410 covering the capping layer 340, an encapsulation layer 420 disposed on an upper surface of the passivation layer 410, and an encapsulation substrate 430 disposed on the encapsulation layer 420.

The display device according to embodiments of the disclosure may include an undercut structure UCS disposed in the undercut area UCA along the display area AA.

In FIG. 3A, it is illustrated that one undercut structure UCS is disposed in the undercut area UCA, but this is exemplary for convenience of description and is not necessarily limited thereto. As illustrated in FIG. 3B, several undercut structures UCS may be disposed in the undercut area UCA.

Referring to FIGS. 3A to 5, the substrate SUB may be a glass substrate or a plastic substrate, and may be formed of various types of films.

A light blocking layer 210 may be disposed on the substrate SUB.

The light blocking layer 210 may be a plurality of signal lines.

For example, the plurality of signal lines may be a GIP output line, a data line, a reference voltage line, a driving voltage line, or the like.

A buffer layer 220 may be disposed on a plurality of signal lines.

The buffer layer 220 serves to protect a thin film transistor (not shown) formed in a subsequent process from impurities such as alkali ions discharged from the substrate SUB.

The buffer layer 220 may be a single layer of silicon oxide (SiOx) or silicon nitride (SiNx) or multiple layers thereof.

Metal layers 230 and 231 may be disposed on the buffer layer 220.

The metal layers 230 and 231 may be gate lines 231.

The metal layers 230 and 231 may include any one of metals such as aluminum (Al), gold (Au), silver (Ag), copper (Cu), tungsten (W), molybdenum (Mo), chromium (Cr), tantalum (Ta), titanium (Ti), or an alloy thereof, but are not limited thereto.

A protective layer 310 including a first portion overlapping the metal layers 230 and 231 and a second portion not overlapping the metal layers 230 and 231 may be disposed on the metal layers 230 and 231.

Referring to FIGS. 4A and 4B, the undercut area may include an undercut structure UC in which the metal layer 231 is positioned inward of a lower portion of the protective layer 310.

In other words, one end of the protective layer 310 may be disposed to protrude outward further than the edge of the metal layer 231.

The undercut structure UC may be formed by wet etching.

Referring to FIGS. 4A and 4B, the undercut structure UCS may have an undercut structure UC including a metal layer 231 under the protection layer 310, and in which the metal layer 231 is positioned inward of the lower portion of the protection layer 310.

In FIG. 4A, it is illustrated that only one undercut structure UCS is disposed, but this is exemplary for convenience of description, and the arrangement is not limited thereto. As illustrated in FIG. 4B, several undercut structures UCS may be disposed.

A bank layer 320 may be disposed on the protective layer 310.

FIGS. 4A and 4B illustrate that one end of the protective layer 310 and one end of the bank layer 320 are substantially the same in the undercut area, but this is exemplary and the disclosure is not necessarily limited thereto.

However, one end of the protective layer 310 and one end of the bank layer 320 are substantially the same in the undercut area according to one embodiment.

The bank layer 320 may include an ultraviolet (UV) blocking material.

As the bank layer 320 includes an ultraviolet blocking material, it is possible to prevent ultraviolet rays from reaching the undercut structure UC that is positioned inward of the lower portion of the protective layer 310 during exposure.

Here, when the bank layer 320 covers the upper surface and the side surface of the protective layer 310, the UV rays do not reach the lower portion of the bank layer 320 including the UV blocking material, so that the photosensitive resin layer 500 to be described below may remain in the undercut structure UC.

However, the disclosure is not limited thereto, and the UV blocking material may or may not be included depending on the type of the photosensitive resin layer disposed in the undercut structure UC to be described below.

For example, when the photosensitive resin layer is a positive photosensitive resin layer, it is preferable to include an ultraviolet blocking material in the bank layer 320.

As another example, when the photosensitive resin layer is a negative photosensitive resin layer, the bank layer 320 does not contain an ultraviolet blocking material.

When the negative photosensitive resin is used as the photosensitive resin, a mask may be used instead of not including a UV blocking material in the bank layer 320 to allow the photosensitive resin layer 500 to be described below to remain in the undercut structure UC.

Meanwhile, a planarization layer (not shown) may be disposed on the protective layer 310.

Referring to FIG. 5, a pixel driving circuit layer 250 including a light blocking layer, a buffer layer, a metal layer, a protective layer, and the like may be disposed on the substrate SUB.

The pixel driving circuit layer 250 may include a pixel driving circuit including a driving transistor.

The light emitting device 330 may be disposed on the pixel driving circuit layer 250.

The light emitting device 330 may include an anode electrode 331, a light emitting layer 333, and a cathode electrode 335.

The anode electrode 331 is a pixel electrode, and may be disposed independently in each subpixel.

The anode electrode 331 may be formed of a metal, an alloy thereof, and a combination of a metal and an oxide metal, and may include a transparent conductive material.

The anode electrode 331 may be formed by stacking a transparent electrode, an opaque electrode, or a transparent electrode and an opaque electrode.

Further, the anode electrode 331 may be a transflective electrode or a reflective electrode.

For example, the anode electrode 331 may be formed of one of ITO, IZO, ITZO, ITO/APC/ITO, AlNd/ITO, Ag/ITO, or ITO/APC/ITO.

The bank layer 320 may be disposed to cover the outer edges, and accordingly, an opening through which light is output from one pixel may be formed.

In other words, the bank layer 320 may be provided in the display area and the non-display area, and an opening through which the anode electrode 331 of each pixel is exposed may be formed in the bank layer 320 provided in the display area, and light may be output through the opening.

The bank layer 320 may be formed of at least one inorganic layer or at least one organic layer.

Further, the bank layer 320 may be formed by stacking at least one inorganic layer and at least one organic layer.

The bank layer 320 may cover the undercut structure UC in the undercut area UCA.

In other words, the bank layer 320 may cover the edge of the protective layer 310 and the metal layers 230 and 231 disposed inward of the lower portion of the protective layer 310.

The light emitting layer 333 may be disposed to cover the anode electrode 331 and the bank layer 320.

The light emitting layer 333 may be any one of an organic light emitting layer, an inorganic light emitting layer, and a quantum dot light emitting layer.

Further, the light emitting layer 333 may include a stacked or mixed structure of an organic light emitting layer (or an inorganic light emitting layer) and a quantum dot light emitting layer.

The light emitting layer 333 may be composed of multiple layers of a hole injection layer, a hole transport layer, a light emitting layer, an electron transport layer, and an electron injection layer to increase light emitting efficiency.

The cathode electrode 335 is disposed on the light emitting layer 333.

The cathode electrode 335 is a common electrode and may be commonly disposed in all the subpixels.

The cathode electrode 335 may be a transflective electrode or a reflective electrode.

Further, the cathode electrode 335 may be formed by stacking a transparent electrode, an opaque electrode, or a transparent electrode and an opaque electrode.

For example, the cathode electrode 335 may be any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), and platinum (Pt), or an alloy of the metal.

For example, when the display device according to the embodiments of the disclosure uses a top emission method in which light is output to the outside through the cathode electrode 335, the cathode electrode 335 may be formed of a transparent metal such as ITO or IZO, or may be formed of a metal mixed material including magnesium (Mg) and silver (Ag).

In this case, the anode electrode 331 may include a transparent electrode and a reflective electrode.

Meanwhile, the capping layer 340 may be disposed on the cathode electrode 335.

The capping layer 340 may function to protect the cathode electrode 335.

Referring to FIG. 5, the light emitting layer 333 and the cathode electrode 335 may be disposed to be disconnected by the undercut structure UC in the undercut area UCA.

In the undercut area UCA, the light emitting layer 333 and the cathode electrode 335 may cover side surfaces of the pixel driving circuit layer 250 and the bank layer 320.

The pixel driving circuit layer 250 may include at least one of the light blocking layer, the buffer layer, the metal layer, and the protective layer.

Referring to FIG. 5, the side surface of the light emitting layer 333 provided in the undercut area UCA may be covered by the cathode electrode 335.

A passivation layer 410 may be disposed on the capping layer 340.

The encapsulation layer 420 and the encapsulation substrate 430 may be disposed on the passivation layer 410.

The encapsulation layer 420 may cover side surfaces and upper surface of the passivation layer 410.

As illustrated in FIG. 5, the encapsulation layer 420 may cover side surfaces of the bank layer 320, the light emitting layer 333, the cathode electrode 335, and the capping layer 340 provided under the encapsulation layer 420, and the upper surface of the capping layer 340.

Accordingly, the encapsulation layer 420 may perform an encapsulation function of blocking the components from the outside.

The encapsulation substrate 430 may be formed of, e.g., at least one inorganic film or at least one organic film or, as another example, may be formed by stacking at least one inorganic film and at least one organic film, or may be a metal encapsulation layer.

In this case, the encapsulation layer 420 and the encapsulation substrate 430 may include an adhesive layer FSP and a metal encapsulation layer FSM.

According to embodiments of the disclosure, when the side surface of the light emitting layer 333 is covered by the cathode electrode 335, it is difficult for moisture and oxygen introduced through the side surface of the light emitting layer provided on the outermost side of the display device to penetrate into the display area, and it is possible to provide a display device capable of delaying the time for moisture and oxygen to penetrate into the display area.

Meanwhile, FIGS. 3A to 5 illustrate a case in which there is only one undercut structure UCS, but this is exemplary and the disclosure is not necessarily limited thereto, and there may be provided several, preferably nine or ten, undercut structures UCS.

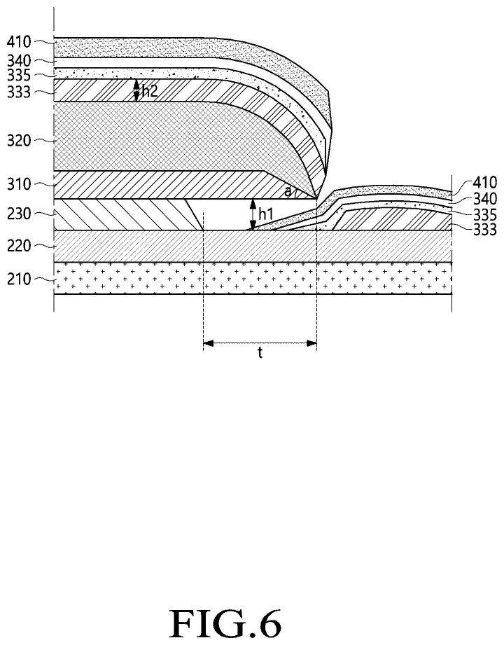

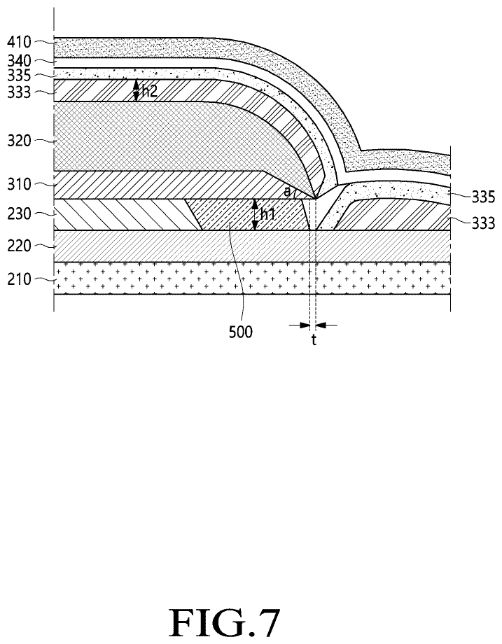

FIGS. 6 and 7 are enlarged cross-sectional views illustrating area Y of FIG. 4A according to embodiments of the disclosure.

Matters regarding the light blocking layer 210, the buffer layer 220, the metal layer 230, the protection layer 310, the bank layer 320, the light emitting layer 333, the cathode electrode 335, the capping layer 340, and the passivation layer 410 of FIGS. 6 and 7 may be substantially the same as those regarding the light blocking layer 210, the buffer layer 220, the metal layers 230 and 231, the protection layer 310, the bank layer 320, the light emitting layer 333, the cathode electrode 335, the capping layer 340, and the passivation layer 410 described with reference to FIGS. 3A to 5.

Referring to FIG. 6, a filler layer may be disposed between the buffer layer 220 and the protective layer 310.

The filler layer may be disposed on the buffer layer 220 and may serve to support components such as the protective layer 310, the bank layer 320, the light emitting layer 333, the cathode electrode 335, the capping layer 340, and the passivation layer 410.

In FIG. 6, although the filler layer is substantially the same as the metal layer 230, the filler layer is not necessarily limited to being composed of only the metal layer 230, but may be a filler layer including other components disposed between the buffer layer 220 and the protective layer 310.

A distance t between one end of the metal layer 230 and one end of the protective layer 310 may be larger than or equal to 0.2 μm and less than or equal to 1.0 μm.

As the distance t between one end of the metal layer 230 and one end of the protective layer 310 decreases, the cathode electrode 335 and the passivation layer 410 may more easily form seamless step coverage.

Referring to FIG. 6, the thickness h2 of the light emitting layer 333 may be smaller than the thickness h1 of the metal layer 230.

As the thickness h2 of the light emitting layer 333 becomes smaller than the thickness h1 of the metal layer 230, i.e., as the thickness h1 of the metal layer 230 becomes larger than the thickness h2 of the light emitting layer 333, moisture penetration may be delayed.

When the thickness h1 of the metal layer 230 is larger than the thickness h2 of the light emitting layer 333, the light emitting layer 333 may be disconnected by the cathode electrode 335 and the passivation layer 410.

The thickness h1 of the metal layer 230 may be 1.2 to 1.3 times the thickness h2 of the light emitting layer 333, and more preferably 1.25 times.

However, the disclosure is not necessarily limited thereto, and the thickness h1 of the metal layer 230 may be smaller than the thickness h2 of the light emitting layer 333. For example, the thickness h1 of the metal layer 230 may be 0.8 to 1 times the thickness h2 of the light emitting layer 333.

Referring to FIG. 6, the protective layer 310 may include an inclined portion overlapping at least a portion of an area that does not overlap the metal layer 230.

Here, the angle between the tangent line at the inflection point of the inclined portion and the bottom surface of the protective layer 310 may be larger than or equal to 20 degrees and less than or equal to 40 degrees.

In one embodiment, the angle between the tangent line at the inflection point of the inclined portion and the bottom surface of the protective layer 310 may be larger than or equal to 20 degrees and less than or equal to 30 degrees.

When the angle between the tangent line at the inflection point of the inclined portion and the bottom surface of the protective layer 310 is larger than or equal to 20 degrees and less than or equal to 40 degrees, the cathode electrode 335 and the passivation layer 410 may more easily form seamless step coverage.

Referring to FIG. 7, a filler layer of a display device according to another embodiment of the disclosure may include a metal layer 230 and a photosensitive resin layer 500.

The metal layer 230 may be a gate line, but is not limited thereto.

The photosensitive resin layer 500 may include a positive photosensitive resin or a negative photosensitive resin.

When the photosensitive resin layer 500 includes a positive photosensitive resin, the photosensitive resin layer may be disposed in the undercut structure UC through an ultraviolet blocking material included in the bank layer 320 without using a mask during exposure.

At least a portion of the bank layer 320 may overlap the photosensitive resin layer 500 to dispose the photosensitive resin layer in the undercut structure UC without using the mask.

In FIG. 7, a case in which the photosensitive resin included in the photosensitive resin layer 500 is a positive photosensitive resin is described as an example, but the disclosure is not limited thereto, and the photosensitive resin may be a negative photosensitive resin.

When the photosensitive resin included in the photosensitive resin layer 500 is a negative photosensitive resin, the UV blocking material may not be included in the bank layer 320.

Accordingly, a mask may be used during exposure.

Here, the mask may block UV rays like the bank layer 320 including the UV blocking material, and thus the UV blocking material may not be included in the bank layer 320.

The photosensitive resin included in the photosensitive resin layer 500 may be at least one of a group II element, a group III element, or Ce.

For example, the photosensitive resin included in the photosensitive resin layer 500 may include at least one of Mg, Ca, Ba, Al, In, Ti, or Ce.

When the photosensitive resin included in the photosensitive resin layer 500 includes at least one of Mg, Ca, Ba, Al, In, Ti, or Ce, the photosensitive resin may trap moisture or oxygen penetrating into the undercut area UCA to delay the penetration time of moisture or oxygen.

Further, as the photosensitive resin layer 500 is disposed on the buffer layer 220 inside the undercut structure UC, the distance between one end of the filler layer and one end of the protective layer may be reduced.

When the distance between one end of the filler layer and one end of the protective layer decreases, the cathode electrode 335 and the passivation layer 410 may more easily form seamless step coverage.

Referring to FIG. 7, the thickness h2 of the light emitting layer 333 may be smaller than the thickness h1 of the filler layer.

As the thickness h2 of the light emitting layer 333 becomes smaller than the thickness h1 of the filler layer, i.e., as the thickness h1 of the filler layer becomes thicker than the thickness h2 of the light emitting layer 333, moisture penetration may be delayed.

When the thickness h1 of the filler layer is thicker than the thickness h2 of the light emitting layer 333, the light emitting layer 333 may be disconnected by the cathode electrode 335 and the passivation layer 410.

The thickness h1 of the metal layer 230 may be preferably 1.2 to 1.3 times the thickness h2 of the light emitting layer 333, and more preferably 1.25 times.

However, the disclosure is not necessarily limited thereto, and the thickness h1 of the metal layer 230 may be smaller than the thickness h2 of the light emitting layer 333. For example, the thickness h1 of the metal layer 230 may be 0.8 to 1 times the thickness h2 of the light emitting layer 333.

Referring to FIG. 7, the protective layer 310 may include an inclined portion overlapping at least a portion of an area that does not overlap the metal layer 230.

Here, the angle between the tangent line at the inflection point of the inclined portion and the bottom surface of the protective layer 310 may be larger than or equal to 20 degrees and less than or equal to 40 degrees.

In one embodiment, the angle between the tangent line at the inflection point of the inclined portion and the bottom surface of the protective layer 310 may be larger than or equal to 20 degrees and less than or equal to 30 degrees.

When the angle between the tangent line at the inflection point of the inclined portion and the bottom surface of the protective layer 310 is larger than or equal to 20 degrees and less than or equal to 40 degrees, the cathode electrode 335 and the passivation layer 410 may more easily form seamless step coverage.

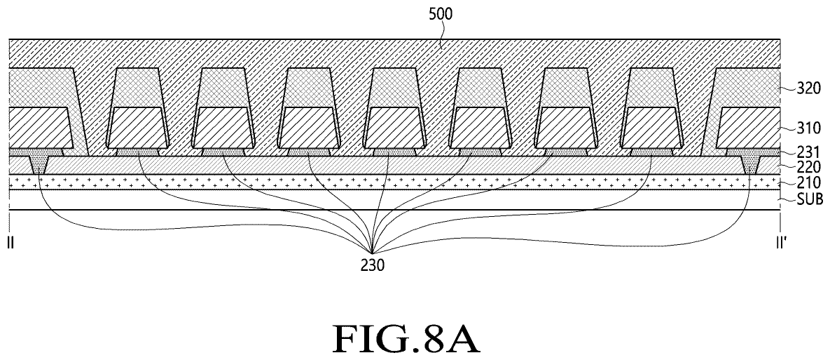

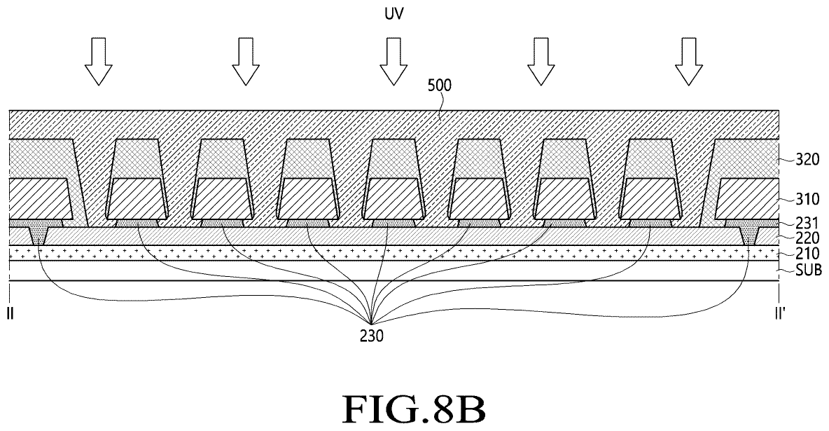

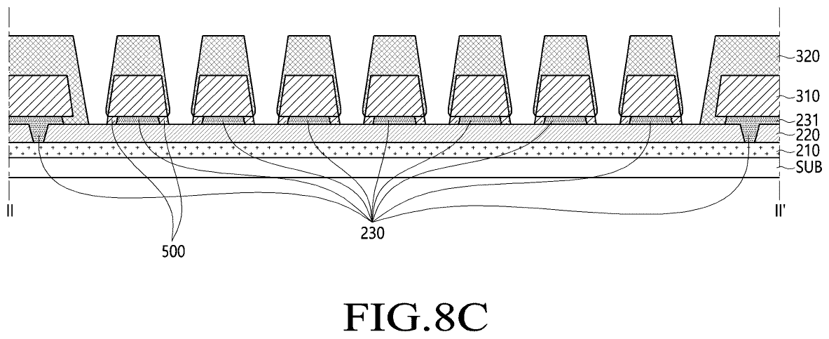

FIGS. 8A, 8B, and 8C are views briefly illustrating a process of forming a partial area of a display panel according to embodiments of the disclosure.

FIGS. 8A to 8C are described with reference to FIG. 4B in which several undercut structures UCS are disposed in the undercut area UCA.

Referring to FIG. 8A, a photosensitive resin composition 500 may cover the bank layer 320 and the buffer layer 220 in areas other than the undercut structure UCS and the undercut area UCA.

The photosensitive resin composition 500 of FIG. 8A may include substantially the same material as the photosensitive resin layer 500 described with reference to FIG. 7.

The photosensitive resin composition 500 of FIGS. 8A to 8C is described as a positive photosensitive resin composition.

Referring to FIG. 8B, the photosensitive resin composition 500 may be exposed to ultraviolet (UV) rays to remove the remaining photosensitive resin composition 500 except for the photosensitive resin composition 500 positioned below the bank layer 320.

Referring to FIG. 8C, the photosensitive resin composition 500 not removed in FIG. 8B may be formed of the photosensitive resin layer 500.

Embodiments of the disclosure described above are briefly described below.

A display device according to embodiments of the disclosure may comprise a substrate including a display area and a non-display area surrounding the display area, a metal layer disposed on the substrate and disposed at a boundary between the display area and the non-display area, a protective layer positioned on the metal layer and including a first portion overlapping the metal layer and a second portion positioned on the substrate and not overlapping the metal layer, and a photosensitive resin layer positioned between the substrate and the second portion.

In the display device according to embodiments of the disclosure, the photosensitive resin layer may include at least one of a group II element, a group III element, or Ce.

In the display device according to embodiments of the disclosure, the photosensitive resin layer may include at least one of Mg, Ca, Ba, Al, In, Ti, or Ce.

In the display device according to embodiments of the disclosure, the photosensitive resin layer may be a positive photosensitive resin layer.

In the display device according to embodiments of the disclosure, the display device may further comprise a bank layer disposed on the protective layer. At least a portion of the bank layer may overlap the photosensitive resin layer.

In the display device according to embodiments of the disclosure, the bank layer may include an ultraviolet (UV) blocking material.

In the display device according to embodiments of the disclosure, the display device may further comprise a light emitting layer disposed on the protective layer and having a thickness smaller than a thickness of the photosensitive resin layer, and a cathode electrode disposed on the light emitting layer.

In the display device according to embodiments of the disclosure, a distance between one end of the photosensitive resin layer and one end of the protective layer positioned in the second portion may be larger than or equal to 0.2 μm and less than or equal to 1.0 μm.

In the display device according to embodiments of the disclosure, the second portion may include an inclined portion overlapping at least a portion of the photosensitive resin layer. An angle between a tangent line at an inflection point of the inclined portion and a bottom surface of the second portion may be larger than or equal to 20 degrees and less than or equal to 40 degrees.

A display device according to embodiments of the disclosure may comprise a substrate including a display area and a non-display area surrounding the display area, a filler layer disposed on the substrate, disposed at a boundary between the display area and the non-display area, and including a first portion including a metal or an alloy thereof and a second portion including a photosensitive resin, and a protective layer positioned on the filler layer.

In the display device according to embodiments of the disclosure, the first portion may be a gate line.

In the display device according to embodiments of the disclosure, the second portion may include at least one of a group II element, a group III element, or cerium Ce.

In the display device according to embodiments of the disclosure, the second portion may include at least one of magnesium Mg, calcium Ca, barium Ba, aluminum Al, indium In, titanium Ti, or cerium Ce.

In the display device according to embodiments of the disclosure, the photosensitive resin may be a positive photosensitive resin.

In the display device according to embodiments of the disclosure, the display device may further comprise a bank layer disposed on the protective layer. At least a portion of the bank layer may overlap the second portion.

In the display device according to embodiments of the disclosure, the bank layer may include an ultraviolet (UV) blocking material.

In the display device according to embodiments of the disclosure, the display device may further comprise a light emitting layer disposed on the protective layer and having a thickness smaller than a thickness of the filler layer, and a cathode electrode disposed on the light emitting layer.

In the display device according to embodiments of the disclosure, a distance between one end of the filler layer and one end of the protective layer may be larger than or equal to 0.2 μm and less than or equal to 1.0 μm.

In the display device according to embodiments of the disclosure, the protective layer may include an inclined portion overlapping at least a portion of the second portion. An angle between a tangent line at an inflection point of the inclined portion and a bottom surface of the protective layer may be larger than or equal to 20 degrees and less than or equal to 40 degrees.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including a display area and a non-display area that surrounds the display area;
a metal layer on the substrate and at a boundary between the display area and the non-display area;
a protective layer on the metal layer, the protective layer including a first portion overlapping the metal layer and a second portion on the substrate and non-overlapping the metal layer; and
a photosensitive resin layer between the substrate and the second portion.

2. The display device of claim 1, wherein the photosensitive resin layer includes at least one of a group II element, a group III element, or cerium.

3. The display device of claim 2, wherein the photosensitive resin layer includes at least one of magnesium, calcium, barium, aluminum, indium, titanium, or cerium.

4. The display device of claim 1, wherein the photosensitive resin layer is a positive photosensitive resin layer.

5. The display device of claim 1, further comprising:
a bank layer on the protective layer,
wherein at least a portion of the bank layer overlaps the photosensitive resin layer.

6. The display device of claim 5, wherein the bank layer includes an ultraviolet blocking material.

7. The display device of claim 1, further comprising:
a light emitting layer on the protective layer, the light emitting layer having a thickness that is smaller than a thickness of the photosensitive resin layer; and
a cathode electrode on the light emitting layer.

8. The display device of claim 1, wherein a distance between one end of the photosensitive resin layer and one end of the protective layer is larger than or equal to 0.2 μm and less than or equal to 1.0 μm.

9. The display device of claim 1, wherein the second portion includes an inclined portion overlapping at least a portion of the photosensitive resin layer, and an angle between a tangent line at an inflection point of the inclined portion and a bottom surface of the second portion is larger than or equal to 20 degrees and less than or equal to 40 degrees.

10. A display device, comprising:
a substrate including a display area and a non-display area that surrounds the display area;
a filler layer on the substrate at a boundary between the display area and the non-display area, the filler layer including a first portion including a metal or an alloy thereof and a second portion including a photosensitive resin; and
a protective layer on the filler layer.

11. The display device of claim 10, wherein the first portion is a gate line.

12. The display device of claim 10, wherein the second portion includes at least one of a group II element, a group III element, or a cerium.

13. The display device of claim 12, wherein the second portion includes at least one of magnesium, calcium, barium, aluminum, indium, titanium, or cerium.

14. The display device of claim 10, wherein the photosensitive resin is a positive photosensitive resin.

15. The display device of claim 10, further comprising:
a bank layer on the protective layer,
wherein at least a portion of the bank layer overlaps the second portion.

16. The display device of claim 15, wherein the bank layer includes an ultraviolet blocking material.

17. The display device of claim 10, further comprising:
a light emitting layer on the protective layer, the light emitting layer having a thickness that is smaller than a thickness of the filler layer; and
a cathode electrode on the light emitting layer.

18. The display device of claim 17, further comprising:
a passivation layer over the cathode electrode,
wherein the light emitting layer is disconnected by the cathode electrode and the passivation layer.

19. The display device of claim 10, wherein a distance between one end of the filler layer and one end of the protective layer is larger than or equal to 0.2 μm and less than or equal to 1.0 μm.

20. The display device of claim 10, wherein the protective layer includes an inclined portion overlapping at least a portion of the second portion, and an angle between a tangent line at an inflection point of the inclined portion and a bottom surface of the protective layer is larger than or equal to 20 degrees and less than or equal to 40 degrees.

21. The display device of claim 10, further comprising:
an undercut area along a boundary between the display area and the non-display area,
wherein the undercut area includes an undercut structure in which the second portion including a photosensitive resin is disposed.
